(19) United States
(12) Patent Application Publication
(10) Pub. No.: US 2026/0196454 A1
(43) Pub. Date: Jul. 9, 2026

(54) System and Method for In situ Atomic Layer Etching (ALE) and Radical-Based Highly Selective Etching (HSE)

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/010,005

(22) Filed: Jan. 5, 2025

(51) Int. Cl. H01J 37/34; H01J 37/32

(52) U.S. Cl. CPC H01J 37/3441; H01J 37/32146; H01J 37/3244; H01J 2237/0473; H01J 2237/332; H01J 2237/334

(57) ABSTRACT

Disclosed herein is a system and method for integrating atomic layer etching (ALE) and radical-based highly selective etching (HSE) within a single process chamber. The system incorporates embodiments featuring a switchable blocking capacitor for eliminating the plasma sheath by grounding the electrostatic chuck (ESC), along with high-power, short RF pulsing techniques for the plasma source. These novel features enable radical-based processes with significantly reduced ion effects during the surface modification step of ALE and radical-based HSE. Application scenarios for in situ ALE and HSE processes are also presented.

### FIELD OF THE INVENTION

The present invention pertains to the field of semiconductor manufacturing, specifically focusing on systems and methods designed to optimize both atomic layer etching (ALE) and radical-based highly selective etching (HSE) processes within a single process chamber.

### BACKGROUND OF THE INVENTION

Reactive ion etching (RIE) is a predominant technology in semiconductor manufacturing. In RIE, various species, including radicals, and ions, concurrently influence the etching process. A key characteristic of RIE is the synergistic interaction between ion and radical fluxes, which significantly enhances the etching rate. This synergistic effect was first described by Coburn and Winters in “Ion- and electron-assisted gas-surface chemistry—an important effect in plasma etching,” published in J. Appl. Phys., vol. 50, pages 3189-3196 (1979). They reported increased silicon etching rates when using an argon ion beam, a XeF₂ neutral beam, and their combination. Effective RIE necessitates the presence of both ion and neutral fluxes to exploit this synergy. However, in modern etching processes, balancing these fluxes, particularly for etching high aspect ratio structures with dimensions shrinking to the nanometer scale, is increasingly complex. Achieving uniform results across 300 mm wafers and consistent repeatability in production pose additional challenges.

ALE has been developed to address the limitations of RIE. The ALE process system has evolved from the RIE process system, with less stringent requirements for achieving uniformity on a 300 mm wafer. However, ALE has unique requirements due to the nature of its process steps. An overview of ALE technology is presented by Karanik et al. in “Overview of atomic layer etching in the semiconductor industry” (J. Vac. Sci. Technol. A33, pages 020802 1-14, 2015) and further discussed by Lill in “Atomic layer processing: semiconductor dry etching technology” (Wiley-VCH GmbH, Boschstr. 12, 69469 Weinheim, Germany, 2021). ALE facilitates the controlled removal of material layers with atomic-level precision and is characterized as an etching technique using sequential self-limiting reactions. The basic ALE process includes two steps: surface modification and material removal. The modification creates a thin reactive layer with a defined thickness, which is easier to remove than the unmodified material. The removal step eliminates this modified layer while preserving the underlying substrate, thus resetting the surface for subsequent cycles. Material removal can be achieved using thermal energy by raising the wafer's temperature or kinetic energy from ions typically derived from inert gases. The isotropic process using thermal energy to remove modified layers is described in U.S. Pat. No. 10,208,383 to George et al. When utilizing energetic ions, the removal is conducted via a sputtering process. The anisotropic ALE process, as described in U.S. Pat. No. 10,727,073 to Tan et al., demonstrates the technology's versatility.

The distinct chemistry, speciation, and plasma energy composition involved in the surface modification and sputtering steps enhance the process by enabling more controlled ion, electron, and neutral species fluxes, thereby widening the process window. This separation facilitates self-limiting reactions, crucial for maintaining the ideality of the etching process-characterized by uniformity, smoothness, and selectivity. Karanik et al., in “Predicting synergy in atomic layer etching” (J. Vac. Sci. Technol. A35, pages 05C302 1-7, 2017), defined ALE synergy as:

$$A L {E}_{s y n e r g y} S ( \% ) = \frac{E P C - ( α + β )}{E P C} \times 100 \% , \qquad [ 1 ]$$

where EPC is “etch per cycle,” representing the total thickness of material removed in one cycle, typically averaged over many cycles. The values of “a” and “B” are (undesirable) contributions from the surface modification step and the sputtering step, respectively. Ideally, synergy will approach 100% with no etching from either step alone. In practice, RIE in the surface modification step is nonzero because of the presence of ions in the plasma, which generates neutrals to modify the surface. In the sputtering step, physical sputtering of the underlying unmodified layer is also nonzero.

It is desirable for the plasma in the surface modification step of the ALE process to be free from ion bombardment. However, the unintended introduction of RIE components during this step presents a persistent challenge. This issue stems from the difficulty in completely preventing ion bombardment of the substrate surface, compromising the ideality of the ALE processes. Modern ALE methodologies struggle to effectively eliminate these RIE components, leading to suboptimal etching outcomes, particularly as device geometries become more complex and smaller in scale. The presence of RIE components in ALE processes can result in non-uniform layer removal and undesirable etching profiles, which are especially problematic in advanced device manufacturing where even minor deviations can significantly impact device performance and yield.

One solution to this problem, as disclosed in U.S. Pat. No. 9,362,131 to Agarwal et al., involves using an electron beam source. During the passivation step (surface modification step), a remote plasma source supplies passivation species to the main process chamber while keeping ion energy below the etching threshold. During the etching operations, the flow from the remote plasma source is stopped, and the ion energy is raised above the etch threshold. This approach introduces an additional remote source, complicating the apparatus and increasing the cost of the process.

Another solution to this problem, as disclosed in U.S. Pat. No. 10,014,192 to Singh, involves using a chamber that is divided into a plasma-generating region and a substrate-processing region by a separating plate structure. This plate structure blocks ions from reaching the substrate while utilizing low-energy metastable species to etch the substrate. However, due to the complete elimination of high-energy ions in the processing region, Singh's method is ineffective for etching high aspect ratio (HAR) structures. In such structures, high-energy ions are essential for reaching the bottom of deep or narrow features. Without sufficient ion energy, the etching process lacks the directional control needed to effectively etch HAR features.

The present invention addresses this critical gap in ALE technology by introducing improved systems and methods that effectively eliminate the RIE component from the surface modification step by either eliminating the plasma sheath or minimizing ion generation during the step. The methodology is consistent with the requirements of a radical-based highly selective etching (HSE). Conventionally, these processes are conducted in separate chambers. Plasma-enhanced ALE anisotropically removes material from a substrate, while radical-based HSE removes material isotropically. In certain cases, ALE and radical-based HSE may need to be conducted sequentially. However, post-ALE surfaces may be sensitive to air exposure, which can cause oxidation and lead to defects. Hence it is desirable to conduct the process steps without breaking the vacuum. Additionally, integrating ALE and HSE within a single chamber could reduce cycle time and overall process costs.

Thus, there is a need for an improved system and method that address these challenges, ensuring ALE process ideality while enhancing the performance and cost-efficiency of both ALE and radical-based HSE processes.

### SUMMARY

In some embodiments, the present invention provides a system and method for integrating in situ atomic layer etching (ALE) and radical-based highly selective etching (HSE) within a single process chamber. This integration significantly reduces cycle time, minimizes process costs, and addresses time-sensitive process steps that are critical in advanced semiconductor manufacturing. In some implementations, this system enables seamless transitions between ALE and HSE processes, reducing risks such as surface oxidation caused by air exposure during process system transfers, which is particularly beneficial for sensitive post-ALE surfaces.

In some embodiments, the system leverages the shared requirement of minimizing ion effects during both the ALE surface modification step (step A) and the HSE step. The surface modification step in ALE, which modifies the substrate surface using reactive radicals without material removal, demands a low-ion or ion-free environment. Similarly, the HSE step requires a radical-only process to achieve high selectivity without the adverse effects of ion bombardment. In some implementations, the system achieves this by suppressing plasma sheath formation or reducing ion generation during these steps, thereby enhancing process ideality.

In some embodiments, two novel techniques are introduced to reduce ion effects. The first technique employs a switchable blocking capacitor that can be activated or deactivated based on the process step. In some implementations, the blocking capacitor is deactivated during the ALE surface modification step or the HSE step, effectively preventing ion bombardment while utilizing generated radicals. The second technique involves using short RF pulses for the plasma source, where the RF signal is modulated by a square wave with a defined duty cycle less than 10% to limit ion generation. In some implementations, this short RF pulsing technique allows radical-based process during ion-sensitive steps.

In some embodiments, the invention provides unique applications, including the etching of high aspect ratio (HAR) structures and processes requiring both anisotropic and isotropic etching within a single chamber. In one example, the system can be used to remove mask layers, including hard mask layers, in situ after the ALE process. The integration of ALE and HSE processes enables enhanced control over sensitive post etching surfaces.

Thus, the present invention provides a system and method that not only optimizes ALE and HSE processes but also enhances manufacturing efficiency, reduces costs, and ensures compatibility with advanced semiconductor fabrication requirements. In some implementations, the system further enables highly controlled and repeatable etching processes, making it suitable for next-generation semiconductor device production.

### BRIEF DESCRIPTIONS OF THE DRAWINGS

FIG. 1A: Illustrates an exemplary plasma process chamber in a first embodiment, featuring a switchable blocking capacitor and short RF pulses for the plasma source.

FIG. 1B: Illustrates an exemplary plasma process chamber in a second embodiment, featuring a tailored waveform generator for bias control and a two-way switch.

FIG. 2: Presents a flowchart describing operational steps of the plasma process chamber with the novel features.

FIG. 3: Depicts exemplary operating modes of the plasma process chamber for ALE and radical-based HSE processes.

FIG. 4: Shows a schematic flow for etching a layer to form a pattern, including in-situ mask layer removal.

FIG. 5: Delineates a step-by-step flowchart describing operations for etching a layer, including in-situ mask layer removal.

FIG. 6: Illustrates a schematic flow for HAR etching, including selective removal of materials from a stack.

FIG. 7: Delineates a flowchart describing operations for HAR etching, including selective removal of materials from a stack.

### DETAILED DESCRIPTIONS

To ensure comprehensive understanding, this section delves into detailed embodiments of the present invention. Although specific details are provided for clarity, modifications and variations that align with the subsequent claims are considered within the scope of this disclosure. Conventional methods and components are highlighted to emphasize the distinct features of the invention.

### Terms Used in This Disclosure

Chamber: A vacuum-sealed environment where semiconductor manufacturing processes, such as etching or deposition, occur.

Vacuum Chamber: A specialized enclosure maintaining vacuum conditions for processes requiring precise pressure control.

Window: A dielectric barrier that allows electromagnetic waves to pass for plasma generation without exposing external components.

Chuck: A substrate support structure, including electrostatic and vacuum chucks, ensuring stability and uniform clamping during processing.

Electrostatic Chuck (ESC): A chuck utilizing electrostatic forces to secure the substrate during processing, enabling uniform thermal and mechanical performance.

Gas Distribution Unit: A system for delivering process gases or precursors, including injectors or showerheads, designed to ensure uniform distribution in the process chamber.

Gas Source: Supplies process gases or precursors, including vaporized materials, to the distribution unit, ensuring precise composition and flow conditions.

Plasma Source: Components for generating plasma for processing, including inductively coupled plasma (ICP) and capacitively coupled plasma (CCP).

Plasma Process Chamber: A vacuum chamber specialized for plasma-based processes like ALE and HSE, enabling precise material modification and removal.

Plasma Atomic Layer Etching (ALE): A process involving alternating surface modification and physical ion sputtering, providing atomic-scale precision in material removal.

Highly Selective Etching (HSE): A radical-based etching process removing target layers with high selectivity, preserving underlying or adjacent materials.

Reactive Ion Etching (RIE): A synergistic etching process using chemical reactions and ion bombardment, offering control over etch precision and uniformity.

Type A Radical Reactor: A plasma reactor configured to generate chemically active radicals while minimizing ion bombardment. Used in the surface modification step of ALE to chemically modify the substrate surface without material removal.

Type A Radicals: Chemically reactive neutral species, typically halogen- or oxygen-based, generated in a plasma and used to selectively modify the substrate surface in ALE processes without material removal.

Type C Radical Reactor: A plasma reactor configured to generate a high flux of chemically reactive radicals for isotropic material removal without ion bombardment. Used in radical-based HSE processes.

Type C Radicals: Reactive neutral species, such as halogen, hydrogen, or oxygen radicals, generated in a plasma and used to remove material layers with high selectivity during HSE processes.

Sputtering Chamber: A plasma reactor configured to perform material removal by physical sputtering, where ions are accelerated toward the substrate by a bias voltage, physically dislodging material from the substrate surface. Used in the sputtering step of ALE processes to remove the modified surface layer.

Sheath: The boundary layer between plasma and the substrate, regulating ion energy and flux critical for etching and deposition.

Bias Unit: A component generating a controlled voltage to accelerate ions toward the substrate, enhancing ion bombardment. It can also contribute to plasma generation in capacitive coupling configurations.

Tailored Waveform Generator: A device producing customized electrical waveforms for precise plasma control, optimizing ion energy distribution.

RF Power Generator: A device supplying radio frequency energy to sustain plasma in the chamber, enabling material modification or removal.

Controller: A central unit managing process parameters, plasma conditions, and chamber operations for optimal performance.

Substrate: The base material, typically a silicon wafer, on which semiconductor devices are fabricated.

Aspect Ratio (AR): The ratio of height to width in a semiconductor feature, critical for defining microstructure geometry and process challenges in HAR etching.

High Aspect Ratio (HAR): Features with significantly higher heights than widths, posing unique challenges in etching and deposition.

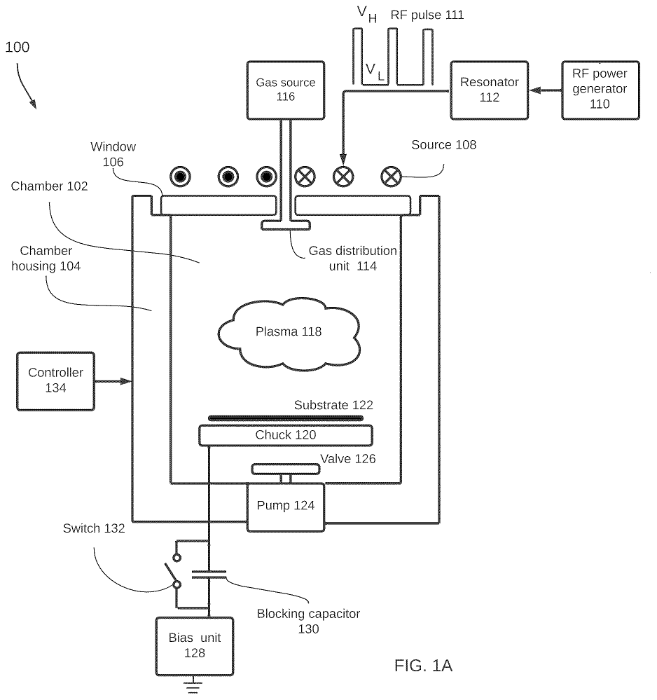

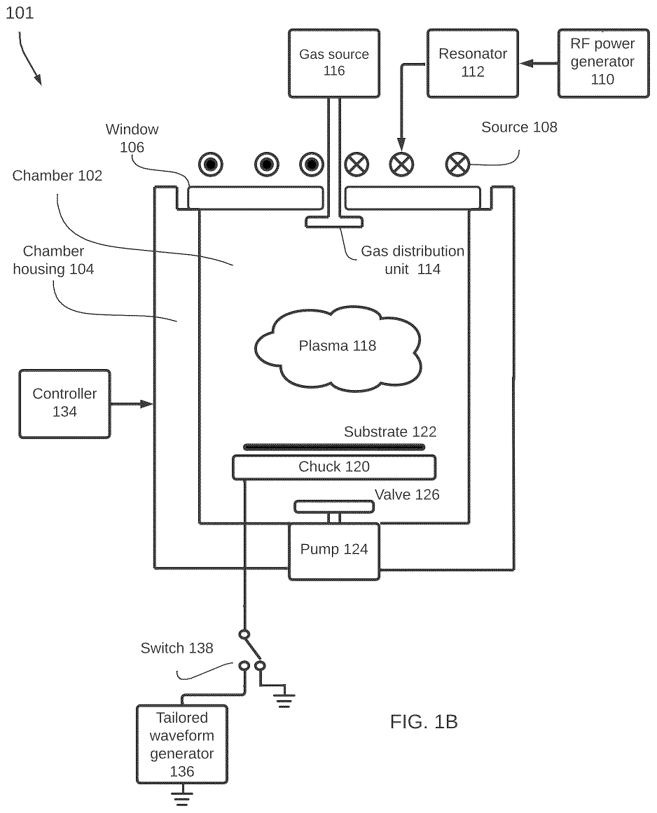

FIG. 1A illustrates an embodiment of a process system, designated as 100, comprising a plasma process chamber, labeled as 102, coordinated by a controller, referred to as 134. The chamber 102 is enclosed by a chamber housing, indicated as 104, which provides a vacuum environment suitable for plasma processing. The housing 104 may be constructed from materials such as aluminum or quartz, with the aluminum surface optionally treated through anodizing or yttrium oxide coating to enhance resistance to plasma exposure.

A hermetically sealed window, labeled as 106, is positioned atop the chamber housing 104. In some embodiments, the window is made of quartz or other plasma-resistant materials, with its interior surface optionally coated with a plasma-resistant material like yttrium oxide. Above the window 106, a plasma source, designated as 108, is situated. The plasma source includes a three-turn coil but may have variations in the number of turns, shapes (e.g., cylindrical or conical), or configurations, depending on operational requirements.

The plasma source 108 is connected to a radio frequency (RF) power generator, labeled as 110, via a resonator, identified as 112, to ensure impedance matching with the plasma load in chamber 102. The RF generator 110 can operate at single or multiple frequencies, including but not limited to 100 kHz, 200 kHz, 400 kHz, 2 MHz, 13.56 MHz, 27 MHz, 40 MHz, and 60 MHz. In some implementations, the RF power is delivered in a pulsed form, represented as 111, modulated by a square wave with a specified duty cycle. This duty cycle, expressed as a percentage, is defined by high (V_{H}) and low (V_{L}) DC voltage levels, with V_{L} being either ground voltage or nonzero.

In inductively coupled plasma (ICP) or transformer coupled plasma (TCP) reactors, plasma ignition involves a transition from E mode (electrostatic mode) to H mode (helicon or high-density mode). E mode relies on capacitive coupling with low plasma density, while H mode uses inductive coupling for high plasma density and ionization efficiency. During RF pulsing, if the duty cycle is too low, plasma power may fall below the threshold required to sustain H mode, forcing the plasma to revert to E mode. Repeated transitions between E mode and H mode increase energy consumption and process inefficiency. Maintaining a minimal sustaining power between pulses keeps the plasma in an “on” state, reducing the time and energy needed to re-establish H mode and ensuring consistent plasma characteristics.

To minimize ion generation while maintaining high radical concentrations, short RF pulses 111 can be designed so that the plasma remains “on” at a minimal RF power. This configuration allows the RF power to rapidly achieve the desired high-power state without repeated E-to-H transitions. Combining this technique with a switchable blocking capacitor ensures ion-free or low-ion plasma conditions for processes like the ALE surface modification step and radical-based HSE, where a high radical concentration and minimal ion energy are critical.

A gas distribution unit, labeled as 114, connects to a gas source, identified as 116, via an aperture in the window 106, ensuring a hermetic seal. The gas source 116 may supply various process gases, and the distribution unit 114 may function as an injector or showerhead. In some configurations, the window 106 integrates the gas distribution unit 114 as a showerhead.

Within the chamber 102, a chuck, labeled as 120, supports a substrate, indicated as 122. The chuck 120 may be an electrostatic chuck (ESC) or vacuum chuck. The chamber 102 is coupled to a pump, labeled as 124, and an associated valve, labeled as 126, to remove unused gases and reaction byproducts, with the withdrawal rate controlled by the valve 126 and pump 124 capacity.

A blocking capacitor, labeled as 130, is included to block direct current (DC) signals, stabilizing the plasma sheath above the substrate 122. This capacitor prevents electron movement to the ground, enabling the accumulation of a negative potential. A parallel switch, labeled as 132, connected to the blocking capacitor 130, allows dynamic control. When the switch 132 is closed, the chuck 120 is grounded via the bias unit 128. When open, the blocking capacitor 130 functions normally. In other configurations, a two-way or series switch may connect the chuck 120 to either ground or the bias unit 128.

During the ALE surface modification step, the switch 132 bypasses the blocking capacitor 130, preventing sheath formation and eliminating reactive ion etching (RIE). In the sputtering step, the switch 132 is open, activating the blocking capacitor 130 to establish a bias for ion acceleration. The controller 134 manages the switch operation via electrical signals, and the switch 132 may include transistors or relays, such as power MOSFETs, or other known mechanisms.

FIG. 1B illustrates another embodiment, designated as 101, in which a tailored waveform generator, labeled as 136, provides a bias for the chuck 120. The tailored waveform generator 136 facilitates tighter ion energy distribution, which is critical for advanced etching processes, particularly for the formation of HAR structures. The tailored waveform generator 136 typically operates at a significantly lower frequency compared to the RF power generator used for the plasma source. Unlike other configurations, the operation of the tailored waveform generator 136 may not require a blocking capacitor.

In this embodiment, a two-way switch, labeled as 138, is employed to deactivate the tailored waveform generator 136 during the surface modification step by grounding the chuck 120. During the sputtering step, the switch 138 activates the tailored waveform generator 136, enabling precise control over the ion acceleration.

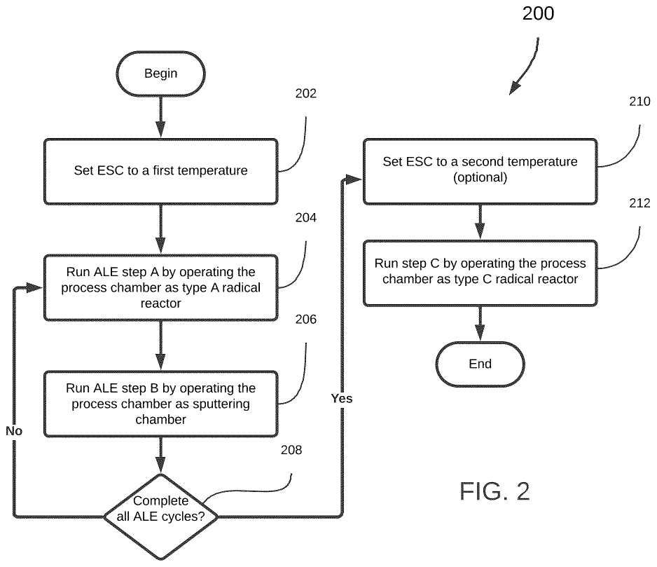

FIG. 2 presents a flowchart for an in situ atomic layer etching (ALE) and radical-based high selectivity etching (HSE) process, labeled as 200. The process 200 begins with step 202, where the chuck 120 is set to a first temperature suitable for the ALE process. This first temperature typically ranges from −30° C. to 150° C.

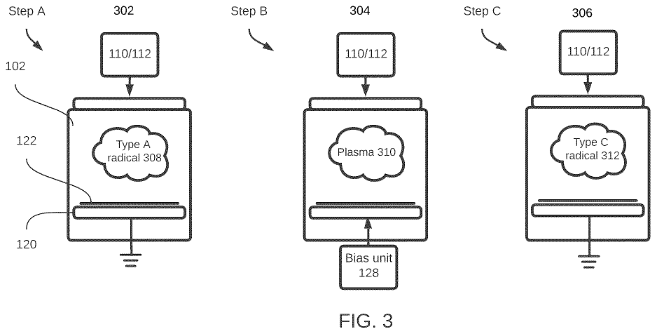

In step 204, the ALE surface modification step (step A) is performed within the plasma process chamber 102, which operates as a type A radical reactor, shown schematically as 302 in FIG. 3. During step A, ions and neutrals, including type A radicals (308), are generated in the plasma 118, while the effects of ions are minimized. In one implementation, the blocking capacitor 132 is deactivated. In another implementation, RF power pulses 111 with very low duty cycle (<10%) is applied. It should be noted that the duty cycle for the RF power pulses can be significantly less than 10%, such as below 1%. In yet another implementation, deactivating the blocking capacitor can be used in combination with the short RF pulses. In the type A radical reactor (302), the surface of the substrate 122 is chemically modified without material removal. For example, during a silicon ALE process, chlorine gas is introduced to generate a chlorine plasma comprising chlorine radicals. These radicals diffuse to the substrate surface and react with surface atoms, forming silicon-chlorine bonds. These bonds exhibit higher bonding energy than silicon-silicon bonds, weakening the underlying silicon-silicon bonds and preparing the material for removal during the subsequent sputtering step (step B).

In step 206, the sputtering step of the ALE (step B) is executed by operating the plasma process chamber 102 as a sputtering chamber, depicted as 304 in FIG. 3, with plasma 310. In the first embodiment, the blocking capacitor 132 is activated, allowing ions to accelerate under the bias established by the bias unit 128. In the second embodiment, the tailored waveform generator 136 is utilized to accelerate ions, enabling a tighter ion energy distribution. An inert gas, such as argon, is typically used as the second process gas during step B.

In step 208, the controller 134 checks whether the ALE cycles are complete. If the cycles are not complete, steps 202 to 206 are repeated until the required number of cycles is achieved. Once completed, the controller 134 transitions the plasma process chamber 102 to execute step 210.

In step 210, the controller 134 adjusts optionally the chuck 120 to operate at a second temperature suitable for the radical-based HSE process. This second temperature is typically higher than the first and may range from room temperature to several hundred degrees Celsius.

In step 212, the controller 134 operates the plasma process chamber 102 as a type C radical reactor, depicted as 306 in FIG. 3. During step C, type C radicals (312) are employed to etch a specific material with high selectivity relative to other materials. To eliminate ion effects during step C, similar techniques as in step A are applied. In one implementation, the blocking capacitor may be deactivated to eliminate the plasma sheath. In another implementation, short RF power pulses are employed. These methods can be used independently or in combination to achieve the desired outcome.

To maintain the cleanliness of the plasma process chamber 102, purging steps may be included between process steps (not shown in FIG. 2). An inert gas, such as nitrogen, may be used for this purpose.

The difference between the type A radical (308) and type C radical (312) lies on that the type A radical is used to chemically modify the surface of the substrate 122 without removing the material while type C radical (312) is employed to remove a material with high selectivity to other materials.

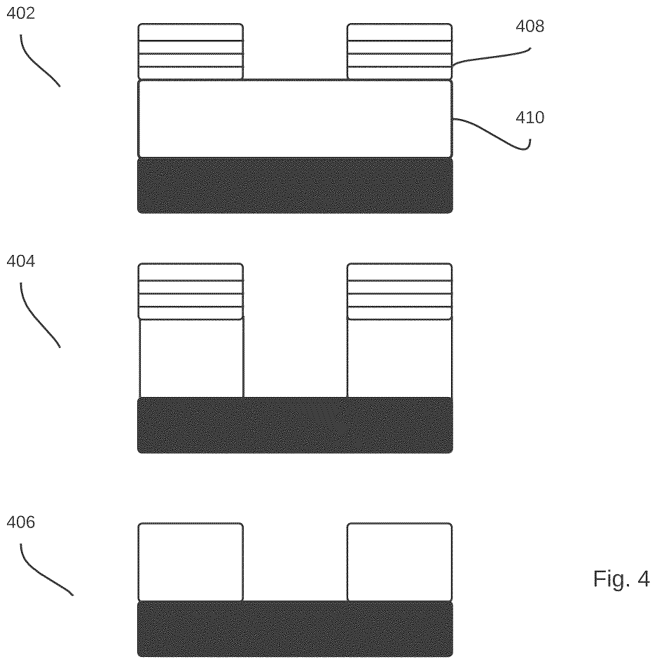

FIG. 4 illustrates a schematic flow for a process involving the etching of a layer and in-situ mask removal in a single plasma process chamber. A substrate, labeled as 402, includes a deposited and patterned mask layer 408 and a target layer 410 to be etched using ALE process. The mask layer 408 may comprise a photoresist layer, potentially enhanced with transfer layers or supplemented with a hard mask, such as a carbon layer. In general, the mask materials can include one or more of the following: carbon, metal-doped carbon, silicon, silicon nitride, silicon oxide, photoresist, or titanium nitride.

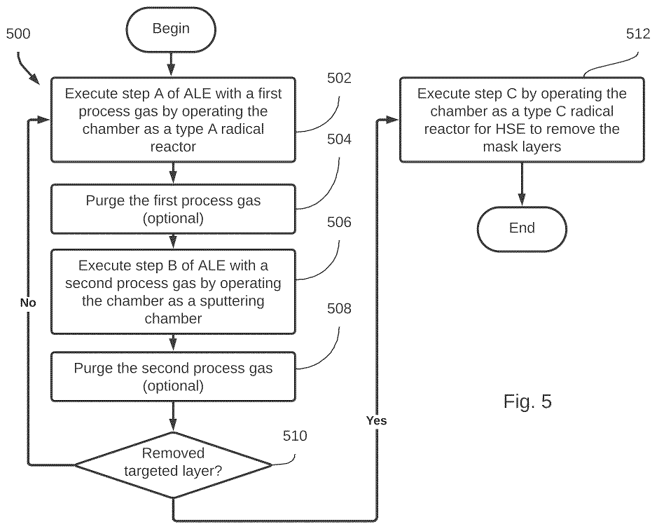

FIG. 5 provides a step-by-step flowchart for the process, labeled as 500. In step 502, the ALE surface modification step (step A) is executed by the controller 134 by introducing a first process gas into the plasma process chamber 102 through the distribution unit 114. The chamber 102 is operated as a type A radical reactor, suppressing ion effects. Type A radicals (308) diffuse into the substrate surface and react with surface atoms to form a modified layer on the surface of the target layer 410.

In step 504, the chamber 102 may optionally be purged before introducing a second process gas. In step 506, the second process gas is introduced into the chamber 102 and the ALE sputtering step (step B) is executed by the controller 134. The chamber 102 is operated as a sputtering chamber. The ions are accelerated by the bias voltage generated by either the bias unit 128 or the tailored waveform generator 136. In step 508, the chamber 102 may optionally be purged to remove the second process gas.

In step 510, the controller 134 determines whether all ALE cycles are complete. If the cycles are not complete, steps 502 to 508 are repeated. Once the cycles are complete, the controller 134 transitions to step 512. A schematic profile after completing all ALE cycles is shown in FIG. 4 as 404.

In step 512, the controller 134 executes the radical-based high selectivity etching (HSE) step (step C) by operating the chamber 102 as a type C radical reactor. During this step, the mask layer 408 is removed using the type C radicals (412) in the same process chamber 102. A schematic profile after step C is shown in FIG. 4 as 406.

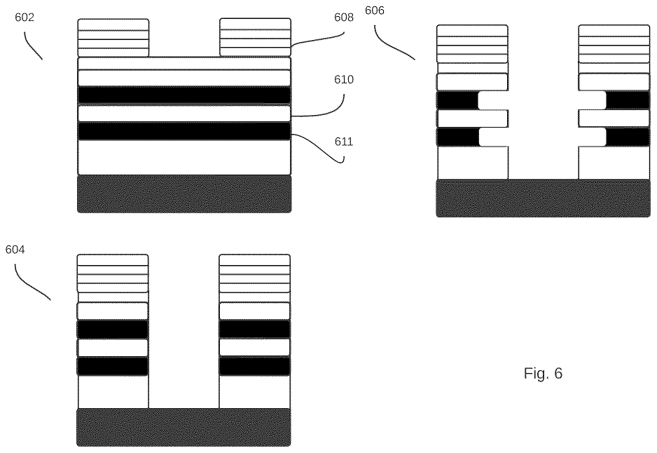

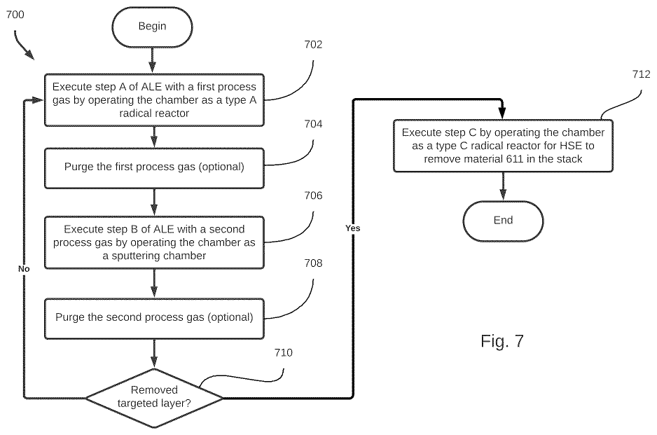

FIGS. 6 and 7 illustrate a second example of using the process system 100 for an HAR etching. In FIG. 6, a substrate, labeled as 602, includes a mask layer 608 and target layers 610 and 611. This structure may represent a 3D NAND stack with alternating layers of silicon oxide and silicon nitride (ONON).

FIG. 7 outlines the process flow, labeled as 700. In step 702, the ALE surface modification step (step A) is executed by the controller 134 by introducing a first process gas into the plasma process chamber 102 through the distribution unit 114. The chamber 102 is operated as a type A radical reactor with suppressed ion effects. Type A radicals (312) diffuse into the substrate surface, deposit, and react with surface atoms to form a modified layer on the surface of the target layer 610 or 611. For an ONON layer, a fluorine- and carbon-containing layer may be deposited, resulting in a modified surface layer on the surface 610/611 stack.

In step 704, the chamber 102 may optionally be purged before introducing a second process gas. In step 706, the ALE sputtering step (step B) is performed by the controller 134 by operating the chamber 102 as a sputtering chamber. Ions are accelerated by the bias voltage produced by either the bias unit 128 or the tailored waveform generator 136 to remove the modified layer. In step 708, the chamber 102 may optionally be purged to evacuate the second process gas.

In step 710, the controller 134 verifies whether all ALE cycles are completed. If the cycles are not complete, steps 702 to 708 are repeated. Upon completion, the controller 134 transitions to step 712. A schematic profile after completing all ALE cycles is shown in FIG. 6 as 604.

In step 712, the controller 134 executes the radical-based HSE step (step C) by operating the chamber 102 as a type C radical reactor. This step removes the layer 611 laterally. A schematic profile after step C is shown in FIG. 6 as 606. In a 3D NAND process flow, 611 represents silicon nitride. The openings formed by removing layer 611 are subsequently used to form metal gates, such as tungsten gates.

1. A plasma process chamber for performing in situ ALE and radical-based HSE processes, comprising:
a plasma source connected to an RF power generator, configured to generate a plasma within the chamber;
a chuck configured to support a substrate;
a bias unit operatively connected to the chuck, configured to generate a bias voltage for accelerating ions during a sputtering step of the ALE process;
a gas distribution unit configured to deliver process gases;
a controller configured to:
operate the chamber in a surface modification step of an ALE process, wherein the plasma is ignited by the plasma source, and the chamber is configured to suppress ion effects;
operate the plasma process chamber in a sputtering step of the ALE process, wherein ions are accelerated by the bias unit to remove the modified layer; and
operate the plasma process chamber in a radical-based HSE step, wherein the chamber is configured to suppress ion effects.

2. The chamber of claim 1, wherein the ion effects are suppressed by employing a switchable blocking capacitor, and the blocking capacitor is deactivated during the surface modification and the radical-based HSE steps.

3. The chamber of claim 1, wherein the ion effects are suppressed by applying pulsed RF power to the plasma source.

4. The chamber of claim 3, wherein the pulsed RF power alternates between a high RF power state and a low RF power state.

5. The chamber of claim 4, wherein the low RF power state corresponds to zero RF power.

6. The chamber of claim 4, wherein the low RF power state corresponds to a non-zero RF power, designed to be as low as possible while sustaining the plasma.

7. The chamber of claim 3, wherein the duty cycle of the pulsed RF power is below 10%.

8. The chamber of claim 1, wherein the ALE process is performed in cycles, and the radical-based HSE step is inserted into a sequence of ALE cycles.

9. The chamber of claim 8, wherein the radical-based HSE process is used to remove mask layers in situ after the ALE process.

10. The chamber of claim 9, wherein the mask layers comprise one or more of the following materials: carbon, metal-doped carbon, silicon, silicon nitride, silicon oxide, photoresist, and titanium nitride.

11. The chamber of claim 8, wherein the radical-based HSE is utilized to remove a material layer after the ALE process forms an HAR structure, and the removed layer is a part of the high aspect ratio structure.

12. A plasma process chamber for minimizing ion effects during plasma-based processes, comprising:
a plasma source connected to an RF power generator, configured to generate a plasma within the chamber, wherein the RF power generator delivers pulsed RF power;
an ESC configured to support a substrate;
a bias unit operatively connected to the ESC, configured to provide a bias voltage through a switchable blocking capacitor, wherein the blocking capacitor is deactivated when minimal ion effects are required; and
a controller configured to minimize the ion effects by controlling the pulsed RF power and/or the switchable blocking capacitor.

13. The chamber of claim 12, wherein the bias unit comprises an RF power generator or a tailored waveform generator.

14. The chamber of claim 12, wherein the pulsed RF power alternates between a high RF power state and a low RF power state.

15. The chamber of claim 14, wherein the low RF power state corresponds to zero RF power.

16. The chamber of claim 14, wherein the low RF power state corresponds to a non-zero RF power, designed as low as possible while sustaining the plasma.

17. The chamber of claim 14, wherein the duty cycle of the pulsed RF power is below 10%.

18. The chamber of claim 12, wherein the chamber is utilized to conduct an in situ ALE and radical-based HSE processes.

19. The chamber of claim 18, wherein the radical-based HSE process is employed to remove mask layers after the ALE process.

20. The chamber of claim 18, wherein the radical-based HSE is utilized to remove a material layer after the ALE process forms an HAR structure, and the removed layer is a part of the high aspect ratio structure.
